(19) United States
(12) Patent Application Publication
(10) Pub. No.: US 2024/0152469 A1
(43) Pub. Date: May 9, 2024

(54) Self-Detecting and Data Rewriting System and Application Method Thereof

(71) Applicant: YAHALALA TECHNOLOGY CO., LTD, Taichung City (TW)

(72) Inventor: Chien-Liang Kuo, Taichung City (TW)

(21) Appl. No.: 17/983,524

(22) Filed: Nov. 9, 2022

(51) Int. Cl. G06F 12/16; G11C 16/10

(52) U.S. Cl. CPC G06F 12/16; G11C 16/105

(57) ABSTRACT

A self-detecting and data rewriting system and application method thereof, mainly comprising: a computer with a data protecting unit installed internally that stores and records at least the computer's boot data and set hotkeys, and an external protection device that has an internal firmware collocated with a data storage unit, the external protection device includes an external connector to be connected with the computer to form information connection, so that the data storage unit is able to update automatically after comparing with and referring to the data protecting unit, to obtain the information of the booting and set hotkeys from the computer and stored and recorded in the external protection device. Thereby, when the computer fails to operate normally, use the external protection device to be connected to the computer so that the computer operating system can be restored and resumed with normal operation.

### FIELD OF THE INVENTION

The present invention relates to the technical field of computer operating system protection and refers in particular to a self-detecting and data rewriting system and application method thereof.

### BACKGROUND OF THE INVENTION

The BIOS (Basic Input/Output System) plays a very important role in a computer, it is in charge of initializing every setting of the computer during boot-up, to keep it in normal working condition and provide basic input/output functions. In the current design of a personal computer, the BIOS is stored in flash memory on the motherboard and allows the user to update the BIOS according to the program provided by the manufacturer. However, if the user does not operate properly or update the contents incorrectly, the BIOS will probably be damaged and the computer will not be able to finish booting normally. Likewise, the same problem exists in the application of Unified Extensible Firmware Interface (UEFI), the new generation of BIOS.

On the other hand, since information technology is more developed and more popular nowadays, data bit streams are widely applied in different aspects, especially, when most users use the output/input units in computers to access data in the storage media of electronic devices, they often face the following two important issues:
1. how to effectively prevent specific data from being stolen or tampered by intentional persons? for instance, reveal of financial information or being destroyed to damage important data and
2. how to take measures to make up in case of data damage? such as improper operation or unexplained damage of the computer during execution of certain applications or operating systems, which affects the computer's failure to boot up or the normal use of applications.

To address the above issues, the protection method mainly used by the prior art can be broken down into two kinds: 1. in terms of data protection, encryption is used for personal important information to prevent the contents of the important information from being accessed by interested persons; 2. in terms of data remediation, a recovery card is used to allow the user who still has an opportunity to determine whether to retain, temporarily store or restore the data which are written into the storage media of the operating system to its original state. However, the current computer protection design is not yet perfect to achieve the best protection effectively and simply. As a result, the computer operating system may still suffer from virus invasion or malicious program control, as well as the files may be destroyed caused by human or accidences. Overall, it cannot protect the computer properly and causes most of the computers a problem of being unable to boot up normally.

### SUMMARY OF THE INVENTION

In view of this, the main purpose of the present invention is to provide a self-detecting and data rewriting system and application method thereof, mainly comprising:
a computer with a data protecting unit internally that stores and records at least the boot data and the set hotkeys of the computer; and
an external protection device that has an internal firmware collocated with a data storage unit, the external protection device includes an external connector to be connected with the computer to form an information connection, so that the data storage unit is able to update automatically after comparing with and referring to the data protecting unit, to obtain the information of booting and hotkeys from the computer, and stored and recorded in the external protection device.

In a preferred embodiment, wherein the data protecting unit may be constituted by a protection application program built into the computer.

In a preferred embodiment, wherein the data protecting unit is further installed in a basic setup unit of the boot process of the computer, such as in a Basic Input/Output System (BIOS) or a Unified Extensible Firmware Interface (UEFI), but it is not a limit in practice.

In a preferred embodiment, wherein the external protection device is a USB flash drive, a memory card, or a data storage device with a burning function, but it is not a limit in practice.

Thereby, the present invention is able to communicate with the external protection device through the unique program installed in the protection application program or the basic setup unit of the boot process of the computer, and then execute a self-detection process on the built-in data of the main system, and modify the relevant settings of the external protection device itself according to the built-in data, so that when the computer fails to operate normally, the external protection device can be connected to the computer to perform a system restoration to restore and resume the computer back to its normal operation state.

### BRIEF DESCRIPTION OF THE DRAWINGS

FIG. 1 is a configuration diagram of the present invention;

FIG. 2 is a flowchart of the present invention;

FIG. 3 is an application diagram of the present invention;

FIG. 4 is a configuration diagram of another embodiment of the present invention; and

FIG. 5 is an application diagram of another embodiment of the present invention.

### DESCRIPTION OF THE PREFERRED EMBODIMENTS

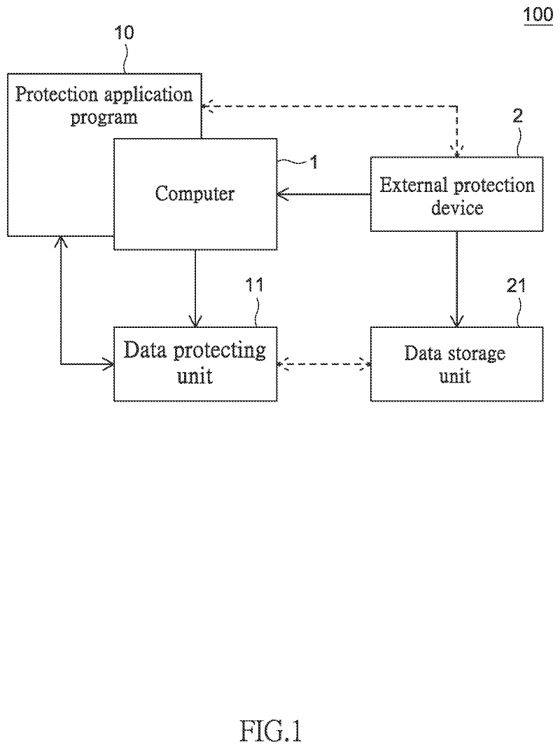

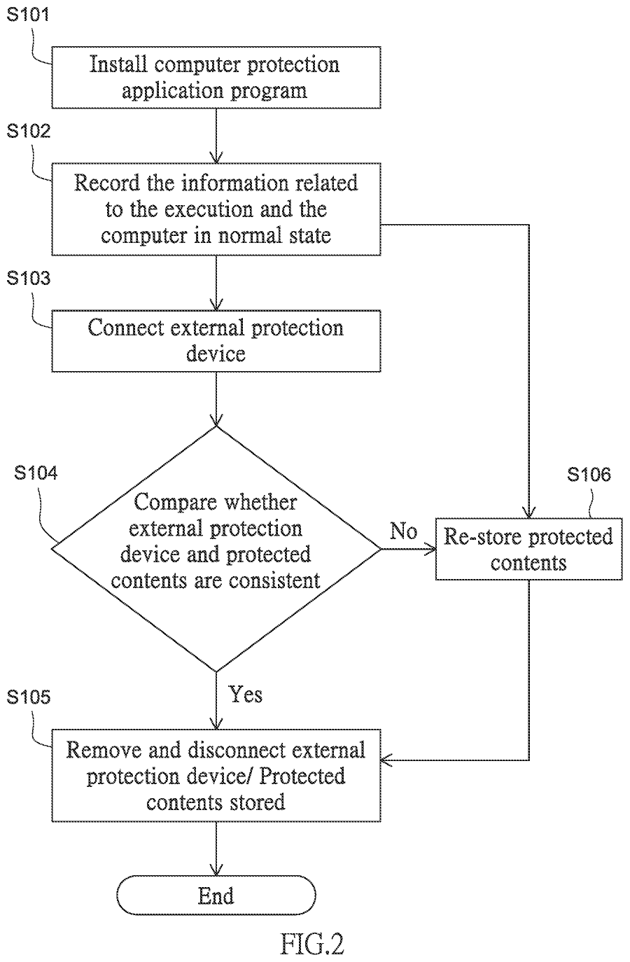

To better understand the substance of the present invention and the effects that can be achieved, specific embodiments will be presented with the drawings and described in detail as follows: Referring to FIGS. 1 to 3, a self-detecting and data rewriting system 100 provided by the present invention mainly consists of:

A computer 1, which is installed with a data protecting unit 11 internally that stores and records at least the boot data and the set hotkeys of the computer 1; and

An external protection device 2, which has an internal firmware collocated with a data storage unit 21, the external protection device 2 includes an external connector to be connected with the computer 1 to form an information connection, so that the data storage unit 21 is able to update automatically after comparing with and referring to the data protecting unit 11, to obtain the information of booting and hotkeys from the computer 1 and stored and recorded in the external protection device 2.

In a preferred embodiment, wherein the data protecting unit 11 is constituted by a protection application program 10 built into the computer 1.

In a preferred embodiment, wherein the external protection device 2 is a USB flash drive, a memory card, or a data storage device with a burning function, but it is not a limit in practice.

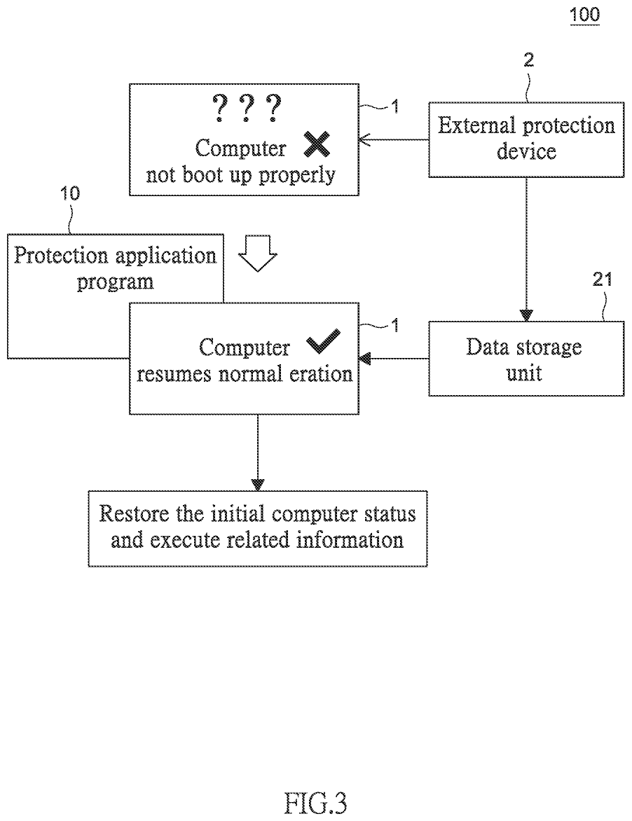

A preferred embodiment as shown in FIG. 3, is the flowchart of the present invention, which is applied and operated as follows:
Step S101: install the protection application program 10 in the computer 1;
Step S102: record the information related to the execution and the computer 1 in a normal state, i.e., the boot data and the set hotkeys of the computer 1 for storage and record;
Step S103: connect the external protection device 2 to the computer 1 to form an information connection;
Step S104: compare the protected contents whether it is consistent between the external protection device 2 and the data protecting unit 11 by the protection application program10, if yes, proceed to step S105, if no, proceed to step S106;
Step S105: if yes, the internal protected contents are stored when the external protection device 1 is removed. The protected contents, namely the boot data and the set hotkeys, of the computer 1 are stored and recorded into the external protection device 1;
Step S106: if no, the protection application program10 of the computer 1 will re-store the protected contents, i.e. the data storage unit 21 will be updated automatically by referring to the data protecting unit 11, enabling the correct boot data and the set hotkeys of the computer 1 to be re-stored and recorded in the external protection device 2, and then the operation will return to step S105 and end, so that an exclusive external protection device 2 for the computer 1 will be made.

Thereby, the present invention is able to communicate with the external protection device 2 through the unique program installed in the protection application program 10 of the computer 1, and then execute a self-detection process on the built-in data of the main system, and modify the relevant settings of the external protection device 2 independently according to the built-in data, so that when the computer fails to operate normally, the external protection device 2 can be connected to the computer 1 to perform a system restoration to restore and resume the computer 1 back to its normal operation state.

More specifically, as shown in FIGS. 1 to 3, which is the first application method of the present invention:
a. First of all, install the protection application program 10 in the computer 1 to enable it to have the data protecting unit 11. When the computer 1 is used for the first time or just started on, the protection application program 10 of the data protecting unit 11 will automatically start to detect the boot data and the set hotkeys of the computer 1, and record the relevant information.
b. Install the data storage unit 21 with the firmware inside of the external protection device 2, and the external protection device 2 includes an external connector to be connected with the computer 1 to form an information connection. Since the external protection device 2 contains a program that can communicate with the protection application program 10 installed in the computer 1, when the external protection device 2 is connected to the computer 1, the protection application program 10 will independently communicate with the external protection device 2 to confirm the data, and if the data is inconsistent, the protection application program 10 will update and rewrite the boot data and the set hotkeys data of the computer 1 into the data storage unit 21 of the external protection device 2.
c. Have the external protection device 2 exclusively paired with the computer 1 to execute a special function. When the computer 1 fails to operate normally, simply connect the external protection device 2 to the computer 1, then the computer 1 will execute the system to restore and resume the system back to its normal operation state.
d. In addition, when the exclusive external protection device 2 is connected to the computer 1, the exclusive external protection device 2 will perform a corresponding action with the computer 1 according to the boot data and the set hotkeys data stored in the interior, and provide the computer 1 with one of the special operation procedures with exclusive authority, among which the special operation procedures is one of the following, special key operation, data encryption, password confirmation, data backup, data restoration, etc., but it is not a limit in practice.

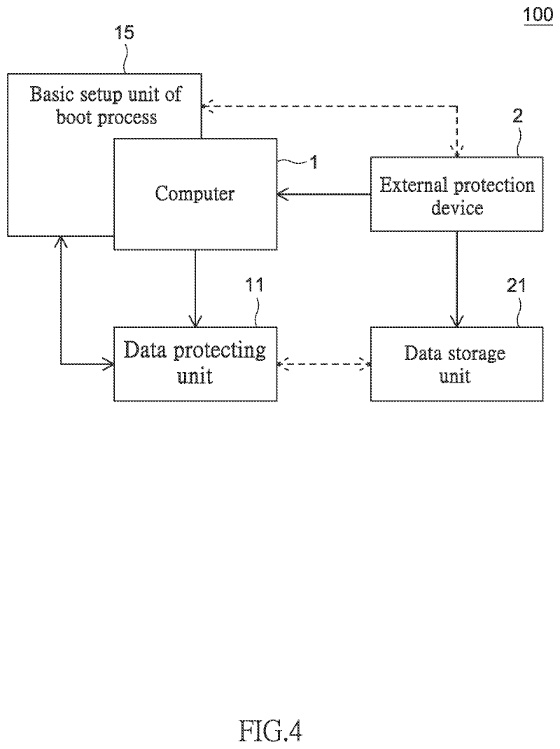

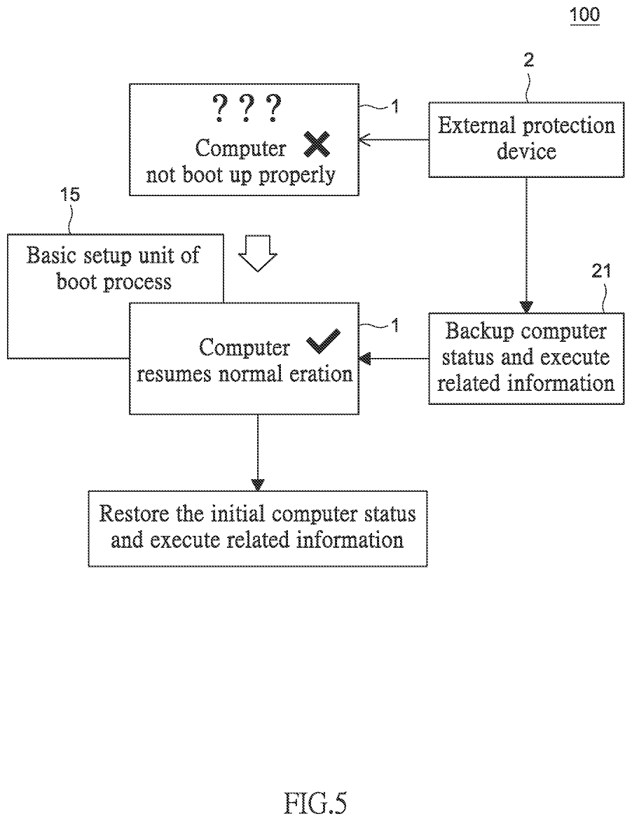

In a preferred embodiment, as shown in FIGS. 4 to 5, wherein the data protecting unit 11 can be further included the installation of which in a basic setup unit 15 of the boot process of the computer 1, such as the Basic Input/Output System (BIOS) or the Unified Extensible Firmware Interface (UEFI), but it is not a limit in practice.

In a preferred embodiment, wherein the external protection device 2 can also be preconfigured with the basic setup unit 15 of the boot process of existing vendor computer models, such as the Basic Input/Output System (BIOS) or the Unified Extensible Firmware Interface (UEFI), and the basic information of the corresponding hotkeys thereof, to enhance the compatibility of the external protection device 2 with the major vendor computers.

More specifically, the second application method of the present invention:
a. First of all, in the basic setup unit 15 of the boot process of the computer 1 further has a unique program for the data protecting unit 11 in correspondence with external protection device 2.
b. When the external protection device 2 is connected with the computer 1, the connecting state of the external protection device 2 will be detected through the unique program of the data protecting unit 11 in the basic setup unit 15 of the boot process, and the relevant boot data and the set hotkeys data of the computer 1 then can be written into the data storage unit 21 of the external device 2 by the data protecting unit 11 in the basic setup unit 15.
c. Have the external protection device 2 exclusively paired with the computer 1 to execute a special function. When the computer 1 fails to boot up normally, simply connect the external protection device 2 to the computer 1, then the computer 1 will execute the system to restore and resume the system back to normal boot operation.
d. In addition, when the exclusive external protection device 2 is connected with the computer 1, the exclusive external protection device 2 will perform a corresponding action with the computer 1 according to the boot data and the set hotkeys data stored in the interior, and provide the computer 1 with one of the special operation procedures with exclusive authority, among which the special operation procedures is one of the following, special key operation, data encryption, password confirmation, data backup, data restoration, etc., but it is not a limit in practice.

By way of the protection application program 10 of the computer 1 or the basic setup unit 15 of the boot process to link with specific keys and to confirm with the external protection device 2, so that the computer 1 must be connected with the exclusive external protection device 2 that has been successfully paired, then it can be changed of the protected data inside of the computer 1 and be executed of the aforementioned special operation procedures. That is, it can effectively prevent others from operating the computer, and will not allow any action that will disturb the normal use or damage the computer by the inappropriate operations, or any action that intrudes improperly to cause destruction will not be allowed to be executed. In this way, it can ensure the safety of the normal use of the computer and prevent the damage caused by random intrusion or improper operation.

While the present invention has been described by means of specific embodiments, numerous modifications and variations could be made thereto by those skilled in the art without departing from the scope and spirit of the present invention set forth in the claims.

1. A self-detecting and data rewriting system, consisting mainly of:
a computer, which is installed with a data protecting unit internally that stores and records at least the boot data and the set hotkeys of the computer; and
an external protection device, which has an internal firmware collocated with a data storage unit, the external protection device includes an external connector to be connected with the computer to form an information connection, so that the data storage unit is able to update automatically after comparing with and referring to the data protecting unit, to obtain the information of the booting and hotkeys from the computer and stored and recorded in the external protection device;
when the computer fails to operate normally, connect the external protection device to the computer to perform a system restoration to restore and resume the computer back to its normal operation state.

2. The self-detecting and data rewriting system according to claim 1, wherein the data protecting unit is constituted by a protection application program built into the computer.

3. The self-detecting and data rewriting system according to claim 1, wherein the external protection device is a USB flash drive, a memory card, or a data storage device with a burning function.

4. The self-detecting and data rewriting system according to claim 1, wherein the data protecting unit is further installed in a basic setup unit of the boot process of the computer.

5. The self-detecting and data rewriting system according to claim 1, wherein the external protection device is preconfigured with the basic setup unit of the boot process of existing vendor computer models, and the basic information of the corresponding hotkeys thereof.

6. The self-detecting and data rewriting system according to claim 4, wherein the basic setup unit of the boot process is the Basic Input/Output System (BIOS) or the Unified Extensible Firmware Interface (UEFI) of the computer.

7. An application method of the self-detecting and data rewriting system, consisting mainly of:
a. first of all, install the protection application program in the computer to enable it to have the data protecting unit; when the computer is used for the first time or just started on, the protection application program of the data protecting unit automatically starts to detect and record the boot data and the set hotkeys data of the computer;
b. install the data storage unit with the firmware inside of the external protection device, and the external protection device includes an external connector to be connected with the computer to form an information connection, then the protection application program will independently communicate with the external protection device to confirm the data, and if the data is inconsistent, the data storage unit will update automatically after comparing with and referring to the data protecting unit, to obtain the information of the boot data and hotkeys from the computer and stored and recorded in the external protection device;
c. have the external protection device exclusively paired with the computer, when the computer fails to operate normally, connect the external protection device to the computer, then the computer will execute the system to restore and resume the system back to its normal operation state; and
d. in addition, connect the exclusive external protection device to the computer to perform a corresponding action with the computer according to the boot data and the set hotkeys data stored in the interior, and provide the computer with one of the special operation procedures with exclusive authority, among which the special operation procedures is one of the following, special key operation, data encryption, password confirmation, data backup, data restoration.

8. The application method according to claim 7, wherein the data protecting unit is further installed within a basic setup unit of the boot process of the computer, when the computer fails to operate normally, connect the external protection device to the computer, then the computer will execute the system to restore and resume the system back to its normal operation state.

9. The application method according to claim 8, wherein the basic setup unit of the boot process is the Basic Input/Output System (BIOS) or the Unified Extensible Firmware Interface (UEFI) of the computer.
